(19) United States
(12) Patent Application Publication
(10) Pub. No.: US 2026/0344249 A1
(43) Pub. Date: Oct. 29, 2026

(54) Display Panel And Electronic Device Including The Same

(71) Applicant: Samsung Display Co., Ltd., Yongin-si (KR)

(72) Inventors: Jin-Su Byun, Yongin-si (KR); Yeongwoo Kwon, Yongin-si (KR); Sikwang Kim, Yongin-si (KR); Yang-Ho Jung, Yongin-si (KR); Gwangmin Cha, Yongin-si (KR)

(73) Assignee: Samsung Display Co., Ltd., Yongin-si (KR)

(21) Appl. No.: 19/422,740

(22) Filed: Dec. 17, 2025

(30) Foreign Application Priority Data
Apr. 24, 2025 (KR) 10-2025-0053757

(51) Int. Cl. H10K 59/80; H10K 59/12; H10K 59/122; H10K 59/131; H10K 102/00; H10K 102/10

(52) U.S. Cl. CPC H10K 59/80522; H10K 59/1201; H10K 59/122; H10K 59/131; H10K 59/80521; H10K 2102/101; H10K 2102/351

(57) ABSTRACT

A display panel is provided that includes a semiconductor portion, first via layer disposed on the semiconductor portion, first and second connection electrodes, pixel defining layer, light-emitting diode, auxiliary electrode, and insulating portion. The first connection electrode is connected to the semiconductor through the first via layer. The second connection electrode is disposed on the first via layer. The pixel defining layer is disposed on the first via layer and has first and second openings. The light-emitting diode includes anode and cathode electrodes, and light-emitting layer. The anode electrode overlaps the first opening and contacts the first connection electrode. The auxiliary electrode includes lower and upper auxiliary electrodes. The lower auxiliary electrode overlaps the second opening and contacts the second connection electrode. The upper auxiliary electrode contacts the cathode electrode and is disposed on the lower auxiliary electrode. The insulating portion contacts the lower auxiliary electrode.

### CROSS-REFERENCE TO RELATED APPLICATIONS

This application claims priority to and the benefit of Korean Patent Application No. 10-2025-0053757, filed on Apr. 24, 2025, the disclosure of which is incorporated by reference herein in its entirety.

### TECHNICAL FIELD

The present disclosure relates to a display panel and an electronic device that includes the display panel.

### BACKGROUND

A display panel generally includes a light-emitting diode, and the light-emitting diode includes an anode electrode, an light-emitting layer, and a cathode electrode. The light-emitting layer emits light in response to power supplied from the anode and cathode electrodes.

Various materials can be used to form the cathode electrode, and the electrical resistance of the cathode electrode may vary depending on the selected material. When the resistance of the cathode electrode is relatively high, a voltage drop may occur across the cathode electrode. This voltage drop can reduce the amount of power supplied to the light-emitting layer, potentially resulting in a decrease in light emitted from certain portions of the display panel and adversely affecting the display quality.

Accordingly, there is a need for display panels with improved display quality.

### BRIEF SUMMARY

The disclosure is intended to solve problems including problems associated with a decrease in light emission from certain portions of a display panel, thereby affecting the display quality. The present disclosure describes a display panel and an electronic device that includes the contemplated display panel. More particularly, the display panel of the present disclosure includes an auxiliary electrode configured to suppress a voltage drop that may occur between cathode electrodes.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some aspects, a display panel is provided that comprises: a semiconductor portion, a first via layer, a first connection electrode, a second connection electrode, a pixel defining layer, a light-emitting diode, an auxiliary electrode, and an insulating portion. The semiconductor portion may include a semiconductor material. The via layer is plated with conductive material and is used to allow electrical connection through layers that are connected through the via layer. In some aspects, the first via layer is disposed on the semiconductor portion. The first connection electrode is disposed on the first via layer and passes through the first via layer and is electrically connected to the semiconductor portion. The second connection electrode is disposed on the first via layer and is spaced apart from the first connection electrode.

In some aspects, the pixel defining layer is disposed on the first via layer, and the pixel defining layer has a first opening and a second opening defined therein. In some aspects, the light-emitting diode comprises an anode electrode, an light-emitting layer, and a cathode electrode. In some aspects, the anode electrode overlaps the first opening of the pixel defining layer, and the anode electrode contacts the first connection electrode. Thus, the anode electrode is electrically connected to the first connection electrode.

In some aspects, the auxiliary electrode comprises a lower auxiliary electrode and an upper auxiliary electrode. In some aspects, the lower auxiliary electrode overlaps the second opening of the pixel defining layer, and the lower auxiliary electrode contacts the second connection electrode. In some aspects, the upper auxiliary electrode is disposed on the lower auxiliary electrode. In some aspects, at least one of the lower auxiliary electrode or the upper auxiliary electrode contacts the cathode electrode.

In some aspects, the insulating portion contacts the lower auxiliary electrode. In some aspects, a first length, measured in a predetermined direction, of a portion of the upper auxiliary electrode not overlapping the lower auxiliary electrode is less than a second length, measured in the predetermined direction, of a portion of the insulating portion not overlapping the lower auxiliary electrode. In some aspects, a length of the portion of the insulating portion not overlapping the upper auxiliary electrode is greater than a distance between the insulating portion and the upper auxiliary electrode.

In some aspects, a thickness of a portion of the insulating portion overlapping the upper auxiliary electrode is greater than a thickness of a portion of the insulating portion not overlapping the upper auxiliary electrode.

In some aspects, a first portion of the insulating portion is disposed between the pixel defining layer and the lower auxiliary electrode, and a second portion of the insulating portion contacts the second connection electrode. In some aspects, at least a portion of the light-emitting layer is disposed on the anode electrode, and the light-emitting layer covers at least a portion of the insulating portion. In some aspects, the cathode electrode covers the light-emitting layer, and contacts the lower auxiliary electrode.

In some aspects, a first length is a length, measured in the predetermined direction, of a portion of the upper auxiliary electrode not overlapping the lower auxiliary electrode, and a second length is a length, measured in the predetermined direction, of a portion of the insulating portion not overlapping the lower auxiliary electrode, a thickness of a portion of the light-emitting layer spaced apart from the lower auxiliary electrode by the first length is less than a thickness of a portion of the light-emitting layer spaced apart from the lower auxiliary electrode by a third length. In some aspects, the third length is greater than the first length, and the third length is less than the second length. In some aspects, a thickness of a portion of the light-emitting layer spaced apart from the lower auxiliary electrode by the second length is less than a thickness of a portion of the light-emitting layer spaced apart from the lower auxiliary electrode by a fourth length. In some aspects, the fourth length is greater than the second length.

In some aspects, the first connection electrode and the second connection electrode are configured to receive different voltages.

In some aspects, the display panel further comprises: a base substrate, a gate insulating layer, a gate portion, and a second via layer. In some aspects, the base substrate is disposed under the semiconductor portion. In some aspects, the gate insulating layer is disposed on the semiconductor portion. In some aspects, the gate portion is disposed between the gate insulating layer and the first connection electrode, and at least a portion of the gate portion overlaps the semiconductor portion. In some aspects, the second via layer is disposed between the first via layer and the pixel defining layer, and the second via layer covers at least a portion of each of the first connection electrode and the second connection electrode.

In some aspects, the display panel further comprises a conductive portion. In some aspects, the conductive portion is disposed between the pixel defining layer and the insulating portion. In some aspects, a fifth length, measured in the predetermined direction, of the conductive portion is less than the second length.

In some aspects, a sixth length, measured in a predetermined direction, of the upper auxiliary electrode is greater than a seventh length, measured in the predetermined direction, of the lower auxiliary electrode. In some aspects, a thickness of the upper auxiliary electrode is less than a thickness of the lower auxiliary electrode.

In some aspects, the insulating portion comprises an insulating material. In some aspects, the conductive portion comprises a transparent conductive material. In some aspects, the lower auxiliary electrode comprises a first metal material. In some aspects, the upper auxiliary electrode comprises a second metal material different from the first metal material. In some aspects, the first connection electrode and the second connection electrode comprise a same conductive material.

In some aspects, a display panel comprises: a transistor, a first via layer, a first connection electrode, a second connection electrode, a pixel defining layer, a light-emitting diode, an auxiliary electrode, and an insulating portion. In some aspects, the transistor comprises an input electrode, an output electrode, and a control electrode. In some aspects, the first via layer is disposed on the transistor. In some aspects, the first connection electrode is disposed on the first via layer, and is electrically connected to either the input electrode or the output electrode. In some aspects, the second connection electrode is positioned on a same layer as the first connection electrode, and the second connection electrode is spaced apart from the first connection electrode. In some aspects, the second connection electrode is positioned on the first via layer.

In some aspects, the pixel defining layer is disposed on the first via layer. In some aspects, the light-emitting diode comprises: an anode electrode, an light-emitting layer, and a cathode electrode. In some aspects, the anode electrode contacts the first connection electrode.

In some aspects, the auxiliary electrode comprises a lower auxiliary electrode and an upper auxiliary electrode. In some aspects, the lower auxiliary electrode contacts the second connection electrode. In some aspects, the upper auxiliary electrode is disposed on the lower auxiliary electrode. In some aspects, at least one of the lower auxiliary electrode or the upper auxiliary electrode contacts the cathode electrode.

In some aspects, the insulating portion contacts the lower auxiliary electrode. In some aspects, a first length, measured in a predetermined direction, of a portion of the upper auxiliary electrode not overlapping the lower auxiliary electrode is less than a second length, measured in the predetermined direction, of a portion of the insulating portion not overlapping the lower auxiliary electrode.

In some aspects, a thickness of a portion of the insulating portion overlapping the upper auxiliary electrode is greater than a thickness of a portion of the insulating portion not overlapping the upper auxiliary electrode.

In some aspects, a first portion of the insulating portion is disposed between the pixel defining layer and the lower auxiliary electrode, and a second portion of the insulating portion contacts the second connection electrode. In some aspects, at least a portion of the light-emitting layer is disposed on the anode electrode and covers at least a third portion of the insulating portion. In some aspects, the cathode electrode covers the light-emitting layer, and the cathode electrode contacts the lower auxiliary electrode.

In some aspects, a first length is a length, measured in the predetermined direction, of a portion of the upper auxiliary electrode not overlapping the lower auxiliary electrode, and a second length is a length, measured in the predetermined direction, of a portion of the insulating portion not overlapping the lower auxiliary electrode, a thickness of a portion of the light-emitting layer spaced apart from the lower auxiliary electrode by the first length is less than a thickness of a portion of the light-emitting layer spaced apart from the lower auxiliary electrode by a third length. In some aspects, the third length is greater than the first length, and the third length is less than the second length. In some aspects, a thickness of a portion of the light-emitting layer spaced apart from the lower auxiliary electrode by the second length is less than a thickness of a portion of the light-emitting layer spaced apart from the lower auxiliary electrode by a fourth length. In some aspects, the fourth length is greater than the second length.

In some aspects, the first connection electrode and the second connection electrode are configured to receive different voltages.

In some aspects, the display panel further comprises: a base substrate and a second via layer. In some aspects, the base substrate ia disposed under the transistor. In some aspects, the second via layer is disposed between the first via layer and the pixel defining layer, and the second via layer covers at least a portion of each of the first connection electrode and the second connection electrode.

In some aspects, the display panel further comprises: a conductive portion disposed between the pixel defining layer and the insulating portion. In some aspects, a fifth length, measured in a predetermined direction, of the conductive portion, is less than the second length.

In some aspects, a sixth length, measured in a predetermined direction, of the upper auxiliary electrode is greater than a seventh length, measured in the predetermined direction, of the lower auxiliary electrode. In some aspects, a thickness of the upper auxiliary electrode is less than a thickness of the lower auxiliary electrode.

In some aspects, the insulating portion comprises an insulating material. In some aspects, the conductive portion comprises a transparent conductive material. In some aspects, the lower auxiliary electrode comprises a first metal material. In some aspects, the upper auxiliary electrode comprises a second metal material different from the first metal material. In some aspects, the first connection electrode and the second connection electrode comprise a same conductive material.

In some aspects, an electronic device of the present disclosure comprises: a display panel, a processor, a memory, and a power module. In some aspects, the display panel is configured to emit light, the processor is configured to control the display panel, the memory is configured to store data necessary for the operation of the display panel or the processor, and the power module is configured to generate or supply power.

In some aspects, the display panel comprises: a semiconductor portion, a first via layer, a first connection electrode, a second connection electrode, a pixel defining layer, a light-emitting diode, an auxiliary electrode, and an insulating portion. In some aspects, the semiconductor portion comprises a semiconductor material. In some aspects, the first via layer is disposed on the semiconductor portion. In some aspects, the first connection electrode is disposed on the first via layer and passes through the first via layer, thereby the first connection electrode being electrically connected to the semiconductor portion. In some aspects, the second connection electrode is disposed on the first via layer, and the second connection electrode is spaced apart from the first connection electrode.

In some aspects, the pixel defining layer is disposed on the first via layer, and the pixel defining layer has a first opening and a second opening defined therein. In some aspects, the light-emitting diode comprises an anode electrode, a light-emitting layer, and a cathode electrode. In some aspects, the anode electrode overlaps the first opening and contacts the first connection electrode.

In some aspects, the auxiliary electrode comprises a lower auxiliary electrode and an upper auxiliary electrode. In some aspects, the lower auxiliary electrode overlaps the second opening, and the lower auxiliary electrode contacts the second connection electrode. In some aspects, the upper auxiliary electrode is disposed on the lower auxiliary electrode. In some aspects, at least one of the lower auxiliary electrode or the upper auxiliary electrode contacts the cathode electrode.

In some aspects, the insulating portion contacts the lower auxiliary electrode. In some aspects, a first length, measured in a predetermined direction, of a portion of the upper auxiliary electrode not overlapping the lower auxiliary electrode is less than a second length, measured in the predetermined direction, of a portion of the insulating portion not overlapping the lower auxiliary electrode. In some aspects, a first length of a portion of the insulating portion not overlapping the upper auxiliary electrode is greater than a distance between the insulating portion and the upper auxiliary electrode.

In some aspects, a thickness of a portion of the insulating portion overlapping the upper auxiliary electrode is greater than a thickness of a portion of the insulating portion not overlapping the upper auxiliary electrode.

In some aspects, a display panel or an electronic device is provided in which an auxiliary electrode is positioned between cathode electrodes to suppress a voltage drop occurring in a cathode electrode.

### BRIEF DESCRIPTION OF THE DRAWINGS

The above and other aspects, features, and advantages of the present disclosure will become more apparent by describing in detail embodiments thereof with reference to the attached drawings in which:

FIGS. 1A and 1B are a perspective view and an exploded perspective view illustrating an electronic device according to an embodiment of the present disclosure;

FIG. 2A is a plan view illustrating a display panel of the present disclosure;

FIG. 2B is an equivalent circuit diagram of the i-th pixel of the display panel shown in FIG. 2A;

FIG. 3A illustrates the display panel of FIG. 2A with first power lines additionally shown;

FIG. 3B is an enlarged view illustrating the pixels and the first power lines of FIG. 2A;

FIG. 4A is a cross-sectional view of the display panel taken along lines I–I′ and II–II′ of FIG. 3B;

FIG. 4B is an enlarged view of a portion of FIG. 4A;

FIGS. 4C and 4D are enlarged views illustrating an auxiliary electrode according to an embodiment of the present disclosure;

FIGS. 5A and 5B are cross-sectional views of the display panel taken along line III–III′ of FIG. 3B;

FIGS. 6A and 6B are views illustrating a method of manufacturing a display panel according to an embodiment of the present disclosure;

FIGS. 7A-7K are views illustrating steps of the method of manufacturing the display panel shown in FIG. 6;

FIG. 8A is a block diagram illustrating an electronic device according to embodiments of the present disclosure; and

FIG. 8B is a view illustrating electronic devices according to embodiments of the present disclosure.

### DETAILED DESCRIPTION

While specific embodiments are illustrated in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

Hereinafter, embodiments of the disclosure will be described with reference to the attached drawings. When describing with reference to the drawings, identical or corresponding components or elements are given the same reference numerals and redundant descriptions are thereof are omitted.

It is to be understood that when an element (or region, layer, portion, or the like) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. If one element is described to be “directly disposed on,” “directly placed on,” “directly arranged on,” “directly connected to,” or “directly coupled to” another element, it shall be construed that there is no other element interposed therebetween.

Moreover, in the accompanying drawings, it is to be understood that the thicknesses, ratios, and dimensions of the elements may not be to exact scale and may have been exaggerated for convenience of explanation, and thus the present disclosure is not necessarily limited to thicknesses, ratios, dimensions, characteristics, and the like, illustrated in the drawings.

It is to be understood that, although the terms “first” and “second” may be used in describing various elements, but the elements shall not be restricted to these terms. The terms are used only for the purpose of distinguishing one element from another element. For instance, the first element may be named the second element, and vice versa, without departing the scope of claims of the present disclosure.

It is further to be understood that unless clearly disclosed otherwise, any expressions in a singular form includes a meaning of a plural form.

It is also to be understood that the term “and/or” includes all of one or more combinations that the associated components may define, and “at least one of A and B” indicates the case where it is A, or B, or both A and B.

Moreover, relative terms, such as “below,” “under,” “beneath,” “lower,” “bottom,” “above,” “over,” “upper,” “top,” and the like are used herein for ease of description to describe one element or feature’s relationship to another element or feature, as illustrated in the drawings. These terms are described in relative terms, with reference to the directions indicated in the drawings. However, it is to be understood that these relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The example term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The example term “below” or “beneath” can therefore encompass an orientation of both above and below.

It will be understood that the term “having/comprising/including”, or “have/comprise/include” and the like is intended to designate a presence of a feature, a characteristic, a number, a step, an operation, an element, a part or combinations thereof, and do not preclude a presence or possibility of addition of one or more other features, characteristics, numbers, steps, operations, elements, parts or combinations thereof.

It is to be understood the coordinate system of the present disclosure is not limited to the orthogonal coordinate system. That is, the x-axis, y-axis, and z-axis are not limited to the three axes on the orthogonal coordinate system and may be interpreted in a broad sense that includes them. For example, the x-axis, y-axis, and z-axis may be orthogonal to each other, but they may also refer to different directions that are not orthogonal to each other.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

In addition, the terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Unless otherwise defined, all terms, including technical terms and scientific terms, used herein have the same meaning as how they are generally understood by those of ordinary skill in the art to which this disclosure pertains. In addition, a term that is defined in a general dictionary shall be construed to have the same meaning in the context of the relevant art, and, unless otherwise defined explicitly, shall not be interpreted to have an idealistic or excessively formalistic meaning.

In some aspects of the present disclosure, if an embodiment can be differently implemented, the specified order of process may be performed differently than the described order. For example, two processes described to be performed sequentially may be performed simultaneously or performed in a reverse order.

In some aspects, an electronic device of the present disclosure may further include a module or device having additional functions in addition to the display function.

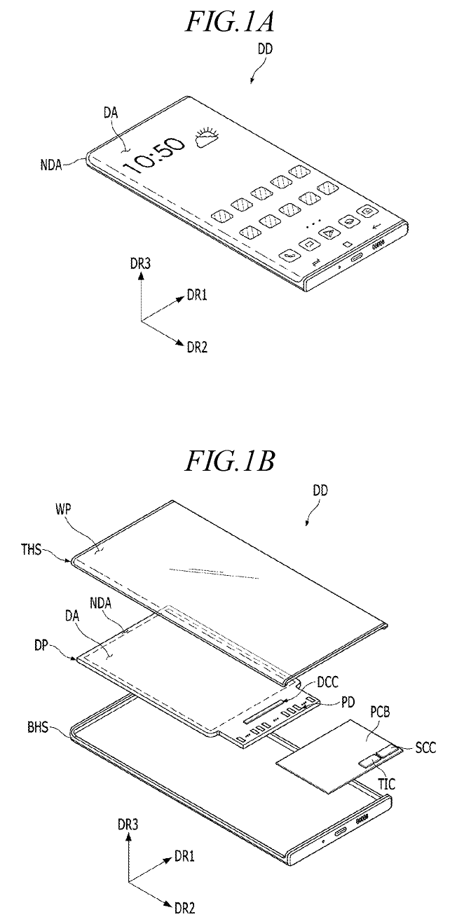

FIGS. 1A and 1B are a perspective view and an exploded perspective view, respectively, illustrating an electronic device DD according to one embodiment of the present disclosure. Referring to FIGS. 1A and 1B, a display area DA and a non-display area NDA may be defined in the electronic device DD.

The display area DA may correspond to a region in which images are displayed. The display area DA may be parallel to a surface defined by a first direction DR1 and a second direction DR2. The second direction DR2 may intersect the first direction DR1. A third direction DR3 may correspond to a normal direction of the display area DA. The non-display area NDA may correspond to a region in which images are not displayed and may surround the display area DA. It should be noted that the shapes of the display area DA and the non-display area NDA in FIGS. 1A and 1B are illustrated by way of example, and the shapes of the display area DA and the non-display area NDA may be modified without limitation as necessary.

Referring to FIGS. 1A and 1B, the electronic device DD may include an upper housing THS, a lower housing BHS, and a display panel DP.

The upper housing THS may include a window member WP and may be positioned above the display panel DP.

The window member WP may be configured to transmit incident light. Specifically, a screen displayed on the display panel DP may be visible to a user through the window member WP. The window member WP may overlap the display area DA. The window member WP may include a transparent material and may be configured to transmit light. The window member WP may include an insulating material. For example, the window member WP may include at least one of glass and plastic.

The lower housing BHS may be positioned below the display panel DP. The lower housing BHS may be configured to protect the display panel DP from external impacts and may accommodate the display panel DP.

The display panel DP may be mounted in the electronic device DD of FIGS. 1A and 1B. A display area DA and a non-display area NDA corresponding to the display area DA and the non-display area NDA of the electronic device DD, respectively, may be defined in the display panel DP.

In one embodiment, the display panel DP may be a self-emissive display panel. For example, the display panel DP may be one of an organic light-emitting display panel, a quantum dot light-emitting display panel, a micro-LED display panel, a liquid crystal display panel, an electrophoretic display panel, and an electrowetting display panel. The light-emitting layer of the organic light-emitting display panel may include an organic light-emitting material. The inorganic light-emitting display panel may include a quantum dot light-emitting display panel and a micro light-emitting display panel based on inorganic materials. Hereinafter, the display panel DP will be described based on an organic light-emitting display panel as an example.

Although the electronic device DD is illustrated as a smartphone in FIGS. 1A and 1B, the electronic device DD of the present disclosure is not limited thereto. In other embodiments, the electronic device DD may include a large display device or a medium or small display device. For example, the large display device may include a television, a monitor, or an electronic billboard. The medium or small display device may include a tablet, a display embedded in a home appliance, a smartwatch, or a smartphone.

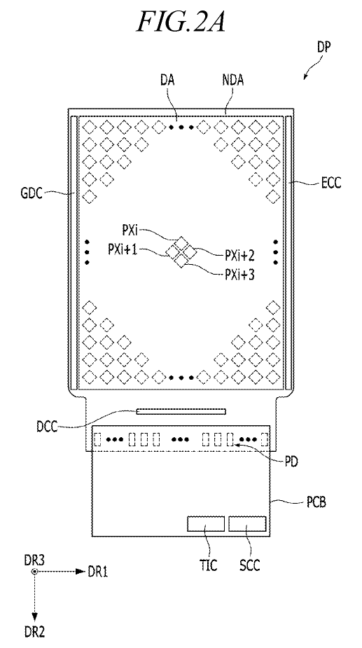

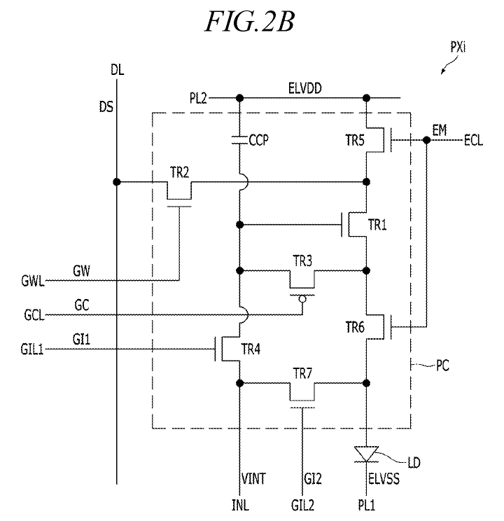

FIG. 2A is a plan view illustrating the display panel DP. FIG. 2B is an equivalent circuit diagram of the i-th pixel PXi of the display panel DP shown in FIG. 2A.

Referring to FIG. 2A, the display panel DP may include a gate driver circuit GDC, an emission control circuit ECC, a data driver circuit DCC, a printed circuit board PCB, a touch input controller TIC, a signal control circuit SCC, a plurality of pads PD, and pixels PX.

The gate driver circuit GDC may be configured to receive a control signal from the signal control circuit SCC and to provide a gate signal to the pixels PX. In one embodiment, the gate driver circuit GDC may be formed simultaneously with the pixels PX through a thin-film process. For example, the gate driver circuit GDC may be implemented in the form of an oxide semiconductor TFT gate driver circuit (OSG) or an amorphous silicon TFT gate driver circuit (ASG).

The emission control circuit ECC may be configured to receive a control signal from the signal control circuit SCC and to provide an emission control signal EM to the pixels PX. The emission control signal EM may be an electrical signal for controlling light emission.

The data driver circuit DCC may be configured to receive a control signal from the signal control circuit SCC and to provide a data signal DS to the pixels PX.

The input-sensing driver circuit TIC and the signal control circuit SCC may be mounted on the printed circuit board PCB and may be configured to receive electrical signals from the plurality of pads PD. The input-sensing driver circuit TIC may be configured to process a signal corresponding to a user’s touch and a signal corresponding to an externally applied pressure.

The signal control circuit SCC (for example, a timing controller) may be configured to control at least one of the input-sensing driver circuit TIC, the gate driver circuit GDC, the data driver circuit DCC, and the emission control circuit ECC. The signal control circuit SCC may be configured to receive image data and control signals from an external graphic controller (not shown). The control signals may include a vertical synchronization signal, a horizontal synchronization signal, a data enable signal, and a clock signal. The vertical synchronization signal may distinguish frame intervals, and the horizontal synchronization signal may distinguish horizontal intervals (that is, row intervals).

Although FIG. 2A illustrates the gate driver circuit GDC and the emission control circuit ECC as separate components positioned apart from each other, the gate driver circuit GDC and the emission control circuit ECC of the present disclosure are not limited thereto. In other embodiments, the gate driver circuit GDC and the emission control circuit ECC may be provided as a single component.

The pixels PX may be provided in plural. The i-th pixel PXi, the (i+1)-th pixel PXi+1, the (i+2)-th pixel PXi+2, and the (i+3)-th pixel PXi+3 may each be any one of the plurality of pixels PX.

Referring to FIG. 2B, each of the plurality of pixels PX may include a light-emitting diode LD and a pixel circuit PC. The structure of the pixel circuit PC in the present disclosure is not limited to the structure illustrated in FIG. 2B. In other embodiments, the pixel circuit PC may be implemented in various forms for driving the light-emitting diode LD.

The pixel circuit PC may include a plurality of transistors TR1–TR7 and a compensation capacitor CCP. The pixel circuit PC may be configured to control an amount of current flowing to the light-emitting diode LD in response to the data signal DS. The pixel circuit PC may include at least one oxide thin-film transistor and a low-temperature polycrystalline silicon (LTPS) thin-film transistor.

The light-emitting diode LD may be configured to emit light with a predetermined luminance in response to the amount of current provided from the pixel circuit PC. For this purpose, a first voltage ELVSS may be set to be greater than a second voltage ELVDD. For example, the light-emitting diode LD may be an organic light-emitting diode (OLED).

Each of the plurality of transistors TR1–TR7 may include an input electrode (or source electrode), an output electrode (or drain electrode), and a control electrode (or gate electrode). In this specification, one of the input electrode and the output electrode may be referred to as a first electrode, and the other may be referred to as a second electrode.

A first electrode of the first transistor TR1 may be electrically connected to the second voltage ELVDD via the fifth transistor TR5, and a second electrode of the first transistor TR1 may be electrically connected to an anode electrode of the light-emitting diode LD via the sixth transistor TR6. The first transistor TR1 may be configured to control the amount of current flowing to the light-emitting diode LD in response to a voltage of the control electrode.

The second transistor TR2 may be positioned between a data line DL and the first electrode of the first transistor TR1. The control electrode of the second transistor TR2 may be electrically connected to a scan control line GWL and may be turned on by a scan control signal GW to electrically connect the data line DL and the first electrode of the first transistor TR1.

The third transistor TR3 may be positioned between the second electrode and the control electrode of the first transistor TR1. The control electrode of the third transistor TR3 may be electrically connected to a compensation control line GCL, and a first electrode of the third transistor TR3 may be electrically connected to the control electrode of the first transistor TR1. The third transistor TR3 may be turned on by a compensation control signal GC to electrically connect the second electrode and the control electrode of the first transistor TR1. Accordingly, when the third transistor TR3 is turned on, the first transistor TR1 may operate as a diode.

The fourth transistor TR4 may be positioned between the compensation capacitor CCP and an initialization power line INL. The control electrode of the fourth transistor TR4 may be electrically connected to a first initialization control line GIL1. The fourth transistor TR4 may be turned on by a first initialization control signal GI1 to provide an initialization voltage VINT to the first electrode of the third transistor TR3.

The fifth transistor TR5 may be electrically connected between a second power line PL2 and the first electrode of the first transistor TR1. The control electrode of the fifth transistor TR5 may be electrically connected to an emission control line ECL that provides the emission control signal EM.

The sixth transistor TR6 may be connected between the second electrode of the first transistor TR1 and the anode electrode of the light-emitting diode LD. The control electrode of the sixth transistor TR6 may be electrically connected to the emission control line ECL that provides the emission control signal EM.

The seventh transistor TR7 may be positioned between the initialization power line INL and the anode electrode of the light-emitting diode LD. The control electrode of the seventh transistor TR7 may be electrically connected to a second initialization control line GIL2 that provides a second initialization control signal GI2. The seventh transistor TR7 may be turned on by the second initialization control signal GI2 to deliver the initialization voltage VINT to the anode electrode of the light-emitting diode LD.

The seventh transistor TR7 may be configured to improve the black display capability of the pixel PXi. Specifically, when the seventh transistor TR7 is turned on, a parasitic capacitor (not shown) of the light-emitting diode LD may be discharged. That is, the seventh transistor TR7 may be turned on to initialize the anode electrode. As a result, light emission of the light-emitting diode LD due to leakage current during black luminance display may be suppressed. Accordingly, the black display capability of the display panel DP may be improved.

The compensation capacitor CCP may be positioned between the second power line PL2 and the control electrode of the first transistor TR1. When the fifth transistor TR5 and the sixth transistor TR6 are turned on, the amount of current flowing through the first transistor TR1 may be determined by the amount of charge stored in the compensation capacitor CCP.

In one embodiment of the present disclosure, each of the first transistor TR1, the second transistor TR2, the third transistor TR3, the fourth transistor TR4, the fifth transistor TR5, the sixth transistor TR6, and the seventh transistor TR7 may be an oxide thin-film transistor or a low-temperature polycrystalline silicon (LTPS) thin-film transistor.

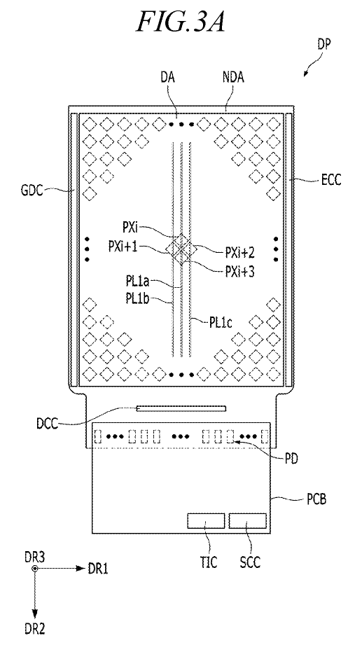

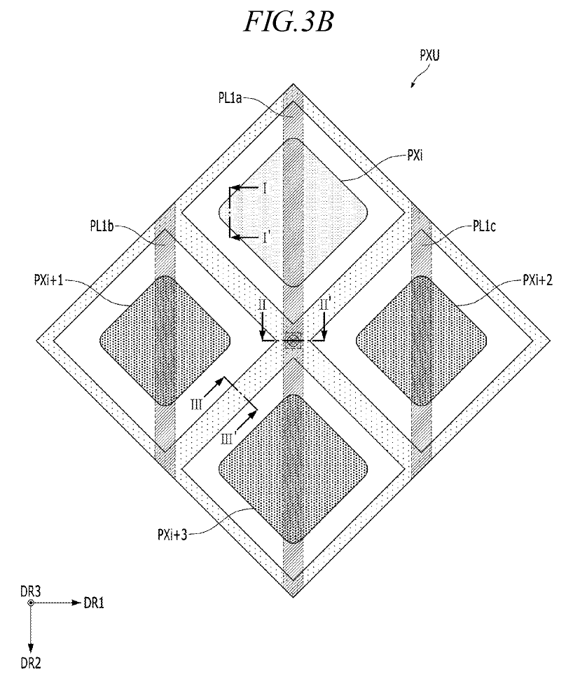

FIG. 3A illustrates the display panel DP of FIG. 2A with first power lines PL1a–PL1c additionally depicted. FIG. 3B is an enlarged view illustrating the pixels PXi–PXi+3 and the first power lines PL1a–PL1c of FIG. 2A.

Referring to FIGS. 3A and 3B, a plurality of first power lines PL1 may be provided. Each of the plurality of first power lines PL1 may overlap at least one of the plurality of pixels PX. Among the plurality of first power lines, one first power line PL1a may overlap the i-th pixel PXi and the (i+3)-th pixel PXi+3, and another first power line PL1b may overlap the (i+1)-th pixel PXi+1, and yet another first power line PL1c may overlap the (i+2)-th pixel PXi+2.

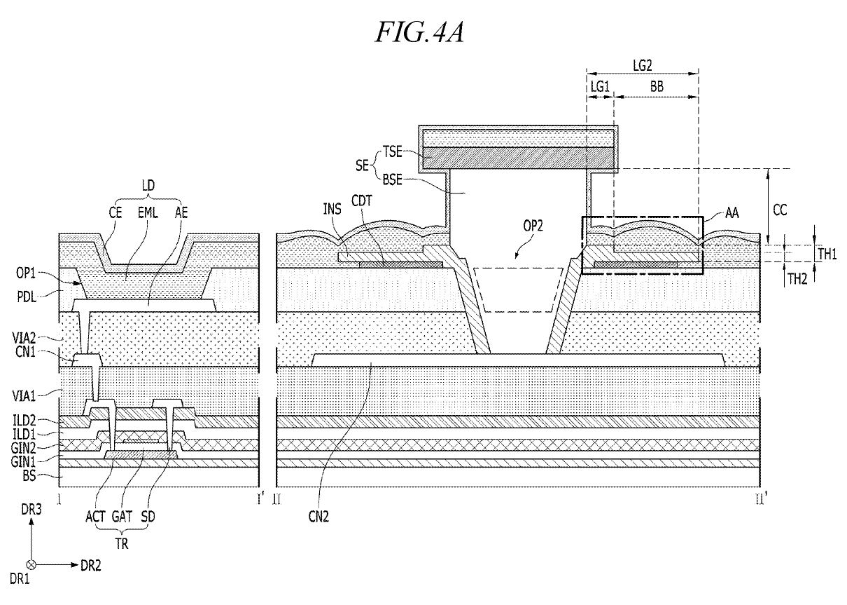

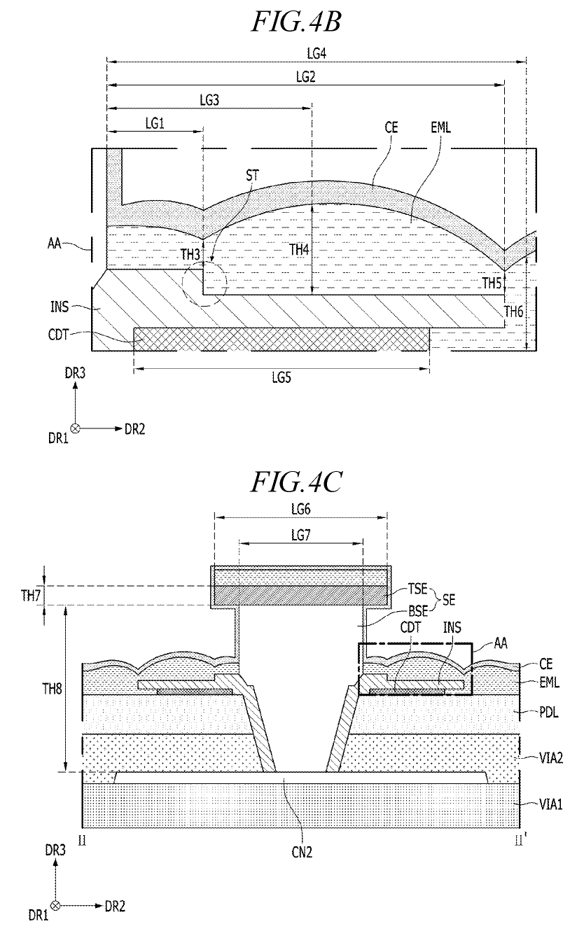

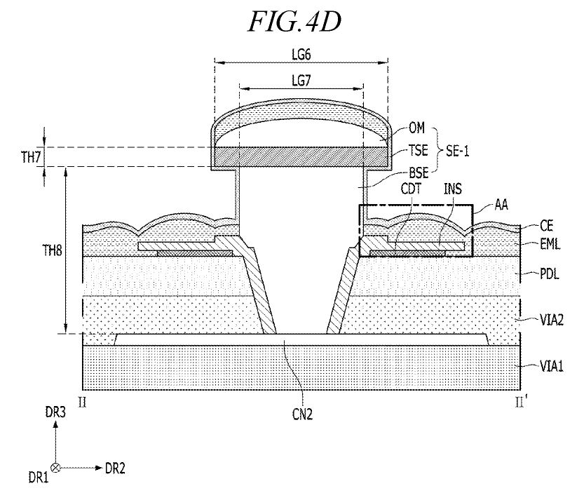

FIG. 4A is a cross-sectional view of the display panel DP taken along lines I–I′ and II–II′ of FIG. 3B. FIG. 4B is an enlarged view of portion AA of FIG. 4A. FIGS. 4C and 4D are enlarged views of auxiliary electrodes SE, SE-1 according to one embodiment of the present disclosure.

Referring to FIG. 4A, the display panel may include a base substrate BS, a buffer layer BF, a first gate insulating layer GIN1, a second gate insulating layer GIN2, a transistor TR, a first interlayer insulating layer ILD1, a second interlayer insulating layer ILD2, a first via layer VIA1, a first connection electrode CN1, a second connection electrode CN2, a second via layer VIA2, a pixel defining layer PDL, a light-emitting diode LD, an auxiliary electrode SE, an insulating portion INS, and a conductive portion CDT.

At least one of the base substrate BS, the buffer layer BF, the first gate insulating layer GIN1, the second gate insulating layer GIN2, the transistor TR, the first interlayer insulating layer ILD1, the second interlayer insulating layer ILD2, the second via layer VIA2, the light-emitting diode LD, and the conductive portion CDT may be omitted.

The buffer layer BF may be disposed on the base substrate BS. The buffer layer BF may be disposed between the base substrate BS and a semiconductor portion ACT. The buffer layer BF may include at least one of an inorganic material and an organic material. For example, the buffer layer BF may include at least one of silicon nitride, silicon oxynitride, silicon oxide, titanium oxide, aluminum oxide, and an acrylic-based organic material.

The transistor TR may include a semiconductor portion ACT, a gate portion GAT, and a source-drain electrode SD.

The semiconductor portion ACT may be disposed on the buffer layer BF and may include a semiconductor material. In one embodiment, the semiconductor material may include at least one of an amorphous silicon semiconductor, a polycrystalline silicon semiconductor, a metal oxide semiconductor, a crystalline oxide semiconductor, and an amorphous oxide semiconductor. For example, the oxide semiconductor may include at least one of indium tin oxide (ITO), indium gallium zinc oxide (IGZO), zinc oxide (ZnO), indium zinc oxide (IZnO), zinc indium oxide (ZIO), indium oxide (InO), titanium oxide (TiO), indium zinc tin oxide (IZTO), and zinc tin oxide (ZTO).

The first gate insulating layer GIN1 may be disposed on the buffer layer BF and may cover the semiconductor portion ACT. The first gate insulating layer GIN1 may include at least one of an organic insulating material and an inorganic insulating material. For example, the first gate insulating layer GIN1 may include at least one of polysiloxane, silicon nitride, silicon oxide, silicon oxynitride, polyacrylate-based compounds, polyimide-based compounds, fluorocarbon compounds, and benzocyclobutene compounds. The first gate insulating layer GIN1 may further include at least one additional layer containing an insulating material.

The gate portion GAT may be disposed between the first gate insulating layer GIN1 and the first connection electrode CN1. A portion of the gate portion GAT overlapping the semiconductor portion ACT may constitute a control electrode of the transistor TR. The gate portion GAT may include a conductive material. For example, the gate portion GAT may include at least one of gold (Au), silver (Ag), aluminum (Al), molybdenum (Mo), chromium (Cr), titanium (Ti), nickel (Ni), neodymium (Nd), and copper (Cu).

The second gate insulating layer GIN2 may be disposed on the first gate insulating layer GIN1 and may cover the gate portion GAT. The gate portion GAT may be disposed between the first gate insulating layer GIN1 and the second gate insulating layer GIN2. The second gate insulating layer GIN2 may include at least one of an organic insulating material and an inorganic insulating material. For example, the second gate insulating layer GIN2 may include at least one of polysiloxane, silicon nitride, silicon oxide, silicon oxynitride, polyacrylate-based compounds, polyimide-based compounds, fluorocarbon compounds, and benzocyclobutene compounds. The second gate insulating layer GIN2 may further include at least one additional layer containing an insulating material.

The source-drain electrode SD may be disposed on the second interlayer insulating layer ILD2 and may be electrically connected to the semiconductor portion ACT. At least a portion of the source-drain electrode SD may constitute either an input electrode or an output electrode of the transistor TR. The source-drain electrode SD may include a metal. For example, the source-drain electrode SD may include at least one of gold (Au), silver (Ag), aluminum (Al), molybdenum (Mo), chromium (Cr), titanium (Ti), nickel (Ni), neodymium (Nd), and copper (Cu).

The first interlayer insulating layer ILD1 may be disposed on the second gate insulating layer GIN2 and may include an insulating material. For example, the first interlayer insulating layer ILD1 may include at least one of polysiloxane, silicon nitride, silicon oxide, and silicon oxynitride.

The second interlayer insulating layer ILD2 may be disposed on the first interlayer insulating layer ILD1 and may include an insulating material. For example, the second interlayer insulating layer ILD2 may include at least one of polysiloxane, silicon nitride, silicon oxide, and silicon oxynitride.

The first via layer VIA1 may be disposed on the second interlayer insulating layer ILD2 and may cover the source-drain electrode SD. The first via layer VIA1 may include an organic material.

The first connection electrode CN1 may pass through the first via layer VIA1 and contact the semiconductor portion ACT. The first connection electrode CN1 may be electrically connected to the semiconductor portion ACT and may be electrically connected to either an input electrode or an output electrode of the transistor TR.

The second connection electrode CN2 may be disposed on the first via layer VIA1 and may be spaced apart from the first connection electrode CN1. The second connection electrode CN2 may form part of the first power line PL1 shown in FIGS. 2B, 3A, and 3B or may be electrically connected to the first power line PL1. The second connection electrode CN2 may be spaced apart from the first connection electrode CN1 in the second direction DR2 and may overlap at least a portion of a second opening OP2.

In one embodiment, the first connection electrode CN1 and the second connection electrode CN2 may include a same conductive material and may be formed through a same process. The first connection electrode CN1 and the second connection electrode CN2 may be positioned on a same layer.

In one embodiment, the first connection electrode CN1 and the second connection electrode CN2 may be configured to receive different voltages. For example, the first connection electrode CN1 may be configured to receive the second voltage ELVDD, and the second connection electrode CN2 may be configured to receive the first voltage ELVSS.

The second via layer VIA2 may be disposed on the first via layer VIA1. The second via layer VIA2 may be positioned between the first via layer VIA1 and the pixel defining layer PDL and may cover at least a portion of each of the first connection electrode CN1 and the second connection electrode CN2. The second via layer VIA2 may include an organic material. In one embodiment of the present disclosure, the second via layer VIA2 may be omitted.

The pixel defining layer PDL may be disposed on the first via layer VIA1. The pixel defining layer PDL may have a first opening OP1 and a second opening OP2 defined therein. In one embodiment of the present disclosure, each of the first opening OP1 and the second opening OP2 may be provided in plural.

The light-emitting diode LD may include an anode electrode AE, an light-emitting layer EML, and a cathode electrode CE. In one embodiment of the present disclosure, the light-emitting diode LD may be defined in a region where the anode electrode AE, the light-emitting layer EML, and the cathode electrode CE overlap each other.

The anode electrode AE may contact and be electrically connected to the first connection electrode CN1. The anode electrode AE may include a conductive material and may be configured to receive the second voltage ELVDD. The anode electrode AE may overlap the first opening OP1.

In one embodiment of the present disclosure, at least a portion of the light-emitting layer EML may be disposed on the anode electrode AE and may cover at least a portion of the insulating portion INS.

The cathode electrode CE may cover the light-emitting layer EML and may contact at least one of a lower auxiliary electrode BSE and an upper auxiliary electrode TSE. The cathode electrode CE may include a conductive material and may be configured to receive the first voltage ELVSS.

The cathode electrode CE may be configured to transmit at least a portion of incident light. The cathode electrode CE may include a transparent conductive oxide (TCO). The TCO may be configured to transmit at least a portion of incident light. For example, the TCO may be one of indium tin oxide (ITO), aluminum-doped zinc oxide (AZO), fluorine-doped tin oxide (FTO), gallium-doped zinc oxide (GZO), niobium-doped titanium oxide (NTO), and CuAlO₂.

Although FIG. 4A illustrates the cathode electrode CE contacting both the lower auxiliary electrode BSE and the upper auxiliary electrode TSE, the cathode electrode CE of the present disclosure is not limited thereto. In another embodiment of the present disclosure, the cathode electrode CE may contact only the lower auxiliary electrode BSE and may not contact the upper auxiliary electrode TSE.

The auxiliary electrode SE may include the lower auxiliary electrode BSE and the upper auxiliary electrode TSE. The auxiliary electrode SE may be spaced apart from the anode electrode AE in the second direction DR2.

The lower auxiliary electrode BSE may overlap the second opening OP2 and may contact the second connection electrode CN2. The lower auxiliary electrode BSE may extend in a third direction DR3 from the second connection electrode CN2.

The upper auxiliary electrode TSE may be disposed on the lower auxiliary electrode BSE and may extend in the second direction DR2 on the lower auxiliary electrode BSE.

In one embodiment of the present disclosure, the lower auxiliary electrode BSE may include a first metal material, and the upper auxiliary electrode TSE may include a second metal material different from the first metal material. The first metal material may be aluminum (Al), and the second metal material may be titanium (Ti).

The insulating portion INS may contact the lower auxiliary electrode BSE and the conductive portion CDT. In one embodiment of the present disclosure, a portion of the insulating portion INS may be disposed between the pixel defining layer PDL and the lower auxiliary electrode BSE, another portion may contact the second connection electrode CN2, and yet another portion may be positioned between the pixel defining layer PDL and the light-emitting layer EML. For example, the insulating portion INS may include an insulating material such as at least one of silicon oxide, silicon oxynitride, and silicon nitride.

The structure of the insulating portion INS may reduce leakage current between the light-emitting layer EML and the cathode electrode CE. This will be described in more detail with reference to FIG. 4B.

The conductive portion CDT may be positioned between the pixel defining layer PDL and the insulating portion INS. The conductive portion CDT may include a transparent conductive material. The transparent conductive material may include at least one of indium tin oxide (ITO), indium gallium zinc oxide (IGZO), and indium zinc oxide (IZnO).

Referring to FIG. 4A, the insulating portion INS may protrude farther in the second direction DR2 than the upper auxiliary electrode TSE.

Specifically, a first length LG1 of a portion of the upper auxiliary electrode TSE not overlapping the lower auxiliary electrode BSE, measured in the second direction DR2, may be less than a second length LG2 of a portion of the insulating portion INS not overlapping the lower auxiliary electrode BSE, measured in the second direction DR2. The first length LG1 may correspond to the protrusion length of the upper auxiliary electrode TSE, and the second length LG2 may correspond to the protrusion length of the insulating portion INS. For example, the second length LG2 may be greater than 2.5 μm.

Referring to FIG. 4A, a protrusion length BB of the insulating portion INS may be greater than a distance CC between the insulating portion INS and the upper auxiliary electrode TSE. The protrusion length BB of the insulating portion INS may be a length measured in the second direction DR2 of a portion of the insulating portion INS not overlapping the upper auxiliary electrode TSE. The protrusion length BB of the insulating portion may correspond to a distance from an end of the upper auxiliary electrode TSE to an end of the insulating portion INS. The distance CC between the insulating portion INS and the upper auxiliary electrode TSE may represent the minimum value of a distance measured in the third direction DR3 between the insulating portion INS and the upper auxiliary electrode TSE.

As the protrusion length of the insulating portion INS increases, leakage current between the light-emitting layer EML and the cathode electrode CE may be reduced. In a conventional display panel, the protrusion length BB of the insulating portion is limited to a value less than or equal to the distance CC between the insulating portion and the upper auxiliary electrode. In contrast, in the present disclosure, the protrusion length BB of the insulating portion INS exceeds the distance CC between the insulating portion INS and the upper auxiliary electrode TSE, and thus, the leakage current described above may be reduced. The reason why increasing the protrusion length of the insulating portion INS reduces the leakage current will be described below with reference to FIG. 4B.Each of the third to fifth thicknesses TH3–TH5 of the light-emitting layer EML refers to the thickness of the light-emitting layer EML positioned between the insulating portion INS and the cathode electrode CE, and the sixth thickness TH6 of the light-emitting layer EML refers to the thickness of the light-emitting layer EML positioned between the pixel defining layer PDL and the cathode electrode CE.

The light-emitting layer EML may include a plurality of layers, and at least one of the plurality of layers may be conductive. At a location where the thickness of the light-emitting layer EML abruptly decreases, the cathode electrode CE and the light-emitting layer EML may be short-circuited, causing leakage current. Referring to FIG. 4B, at the end of the insulating portion INS, the thickness of the light-emitting layer EML may decrease, and leakage current may occur due to the reduction in the thickness of the light-emitting layer EML.

Moreover, the thinner the light-emitting layer EML is, the more likely leakage current is to occur due to the thickness reduction of the light-emitting layer EML. During the deposition process of the light-emitting layer EML, the upper auxiliary electrode TSE may function as a shielding mask. Thus, as the light-emitting layer EML is positioned closer to the lower auxiliary electrode BSE, its thickness may decrease, and as it is positioned farther from the lower auxiliary electrode BSE, its thickness may increase. In other words, the closer the light-emitting layer EML is to the lower auxiliary electrode BSE, the greater the possibility of leakage current caused by a reduction in the thickness of the light-emitting layer EML

Therefore, the farther the end of the insulating portion INS is spaced apart from the lower auxiliary electrode BSE, the lower the likelihood of the aforementioned leakage current. In the present disclosure, the end of the insulating portion INS is spaced farther from the lower auxiliary electrode BSE compared to the prior art, thereby further reducing the possibility of leakage current.

In this specification, a step ST is defined as a portion where the thickness of the insulating portion INS changes from a first thickness TH1 to a second thickness TH2. Referring to FIG. 4A, the first thickness TH1 of a portion of the insulating portion INS overlapping the upper auxiliary electrode TSE may be greater than the second thickness TH2 of a portion of the insulating portion INS not overlapping the upper auxiliary electrode TSE.

In this specification, a halftone mask refers to a mask that fully transmits light, partially transmits light, or completely blocks light.

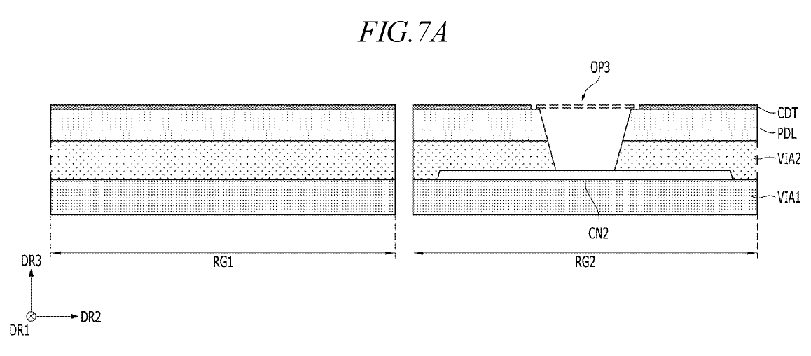

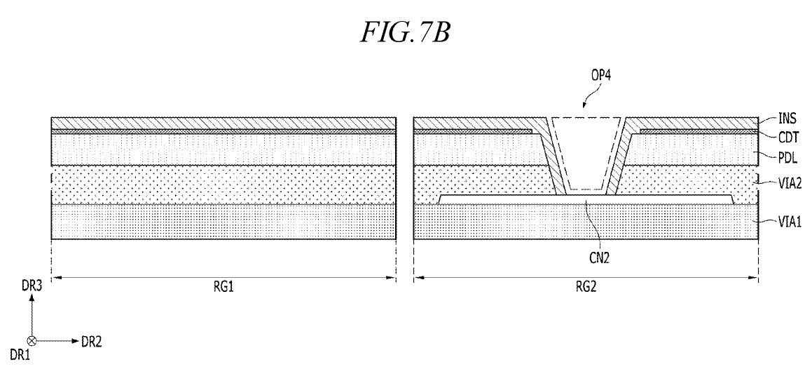

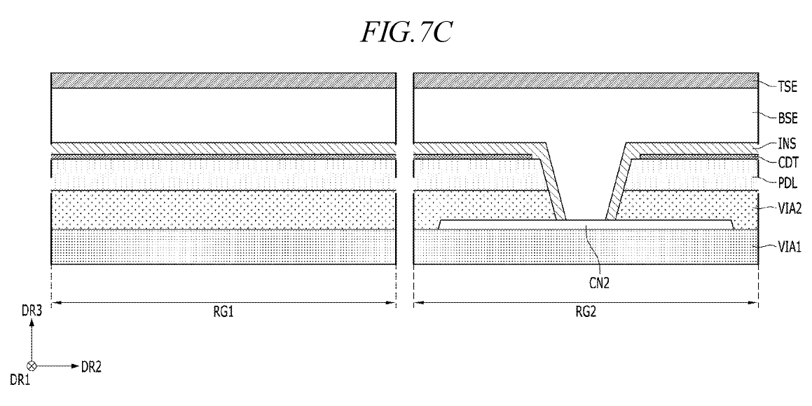

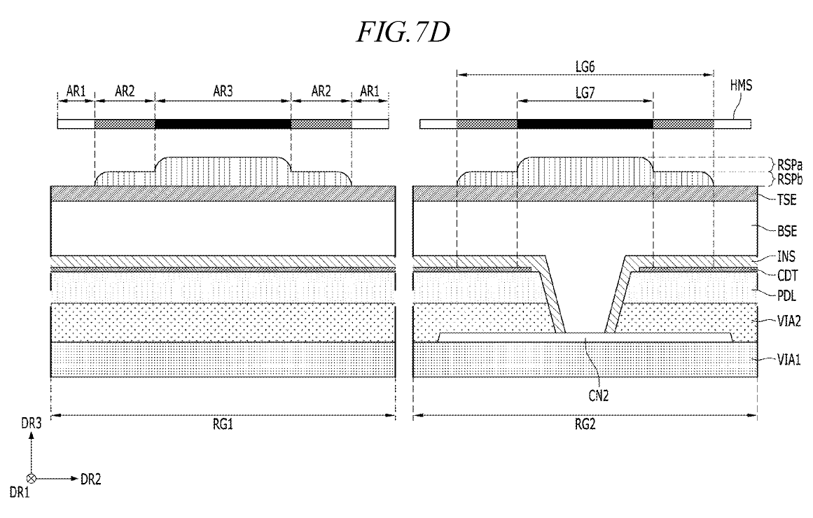

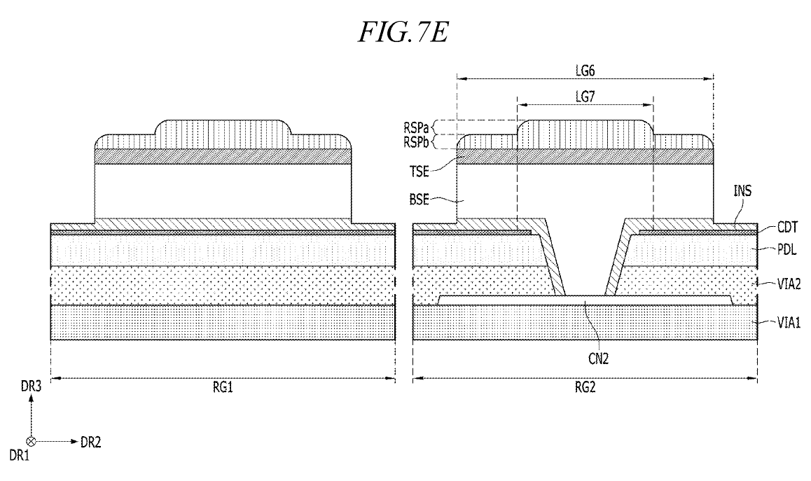

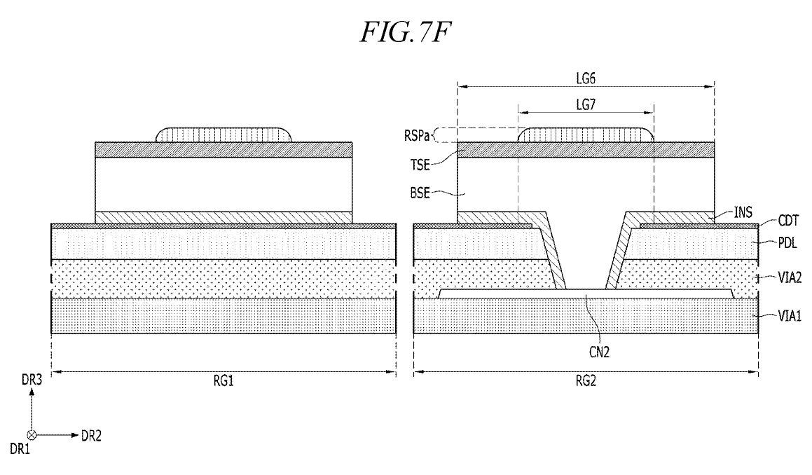

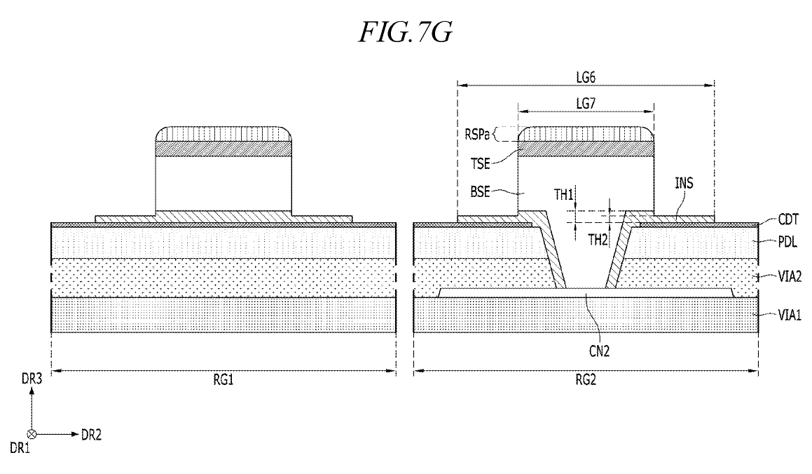

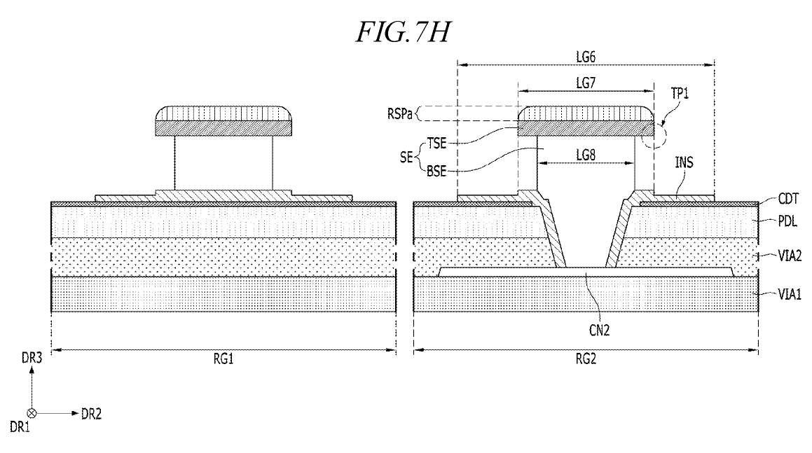

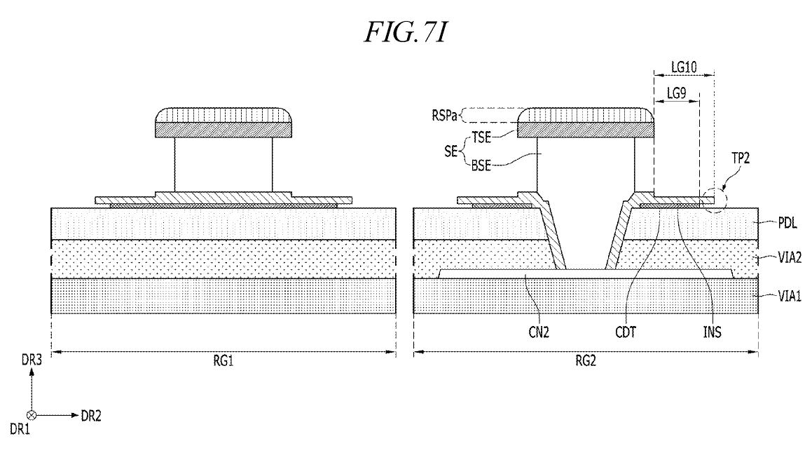

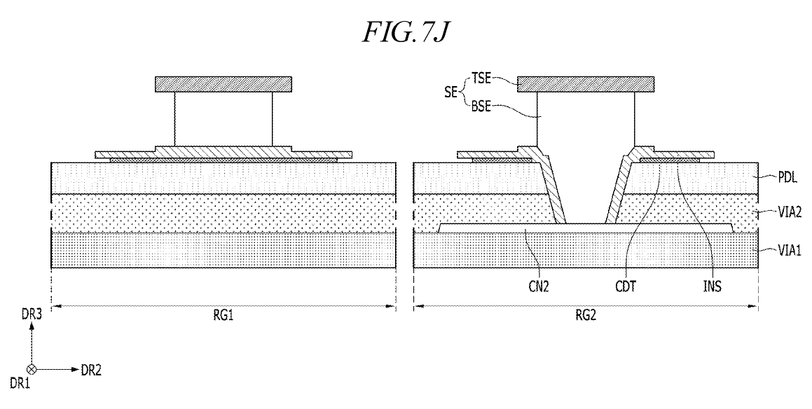

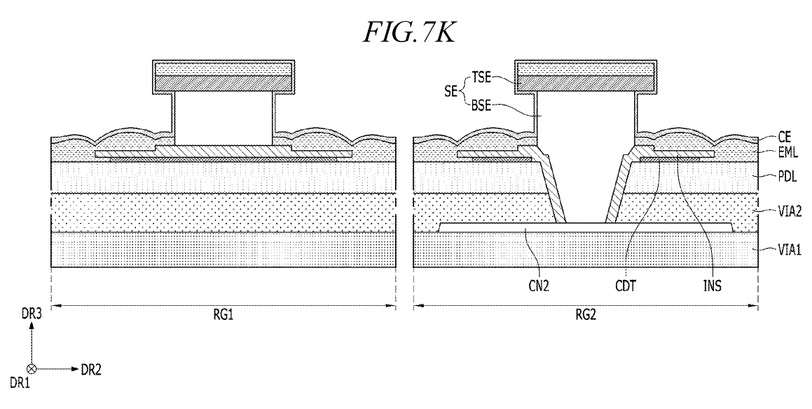

In conventional structures, the upper auxiliary electrode TSE was used as a mask or an additional mask was employed for etching the insulating portion INS. In contrast, in the present disclosure, the insulating portion INS may be etched using a halftone mask (see FIGS. 7D-7G), allowing the protrusion length BB of the insulating portion INS to be determined independently of the upper auxiliary electrode TSE. Thus, by employing the present disclosure, the protrusion length BB of the insulating portion INS may be increased without requiring an additional mask and regardless of the upper auxiliary electrode TSE.

In addition, a plurality of regions AR1–AR3 that transmit light in different amounts may be defined in the halftone mask. Accordingly, the degree and presence of etching of the insulating portion INS may vary based on the boundaries of the aforementioned regions (AR1–AR3 shown in FIG. 7D). As a result, the step ST may be formed at a portion of the insulating portion INS overlapping the boundaries of the aforementioned regions (AR1–AR3 shown in FIG. 7D).

Referring to FIG. 4B, a portion of the light-emitting layer EML spaced apart from the lower auxiliary electrode BSE by the first length LG1 may correspond to a boundary between a second region AR2 and a third region AR3. A portion spaced apart by the second length LG2 may correspond to a boundary between a first region AR1 and the second region AR2. The thickness of the light-emitting layer EML may change at a portion spaced apart from the lower auxiliary electrode BSE by a third length LG3. The third length LG3 may be greater than the first length LG1 and smaller than the second length LG2.

Specifically, a third thickness TH3 of the light-emitting layer EML at a portion spaced apart from the lower auxiliary electrode BSE by the first length LG1 may be smaller than a fourth thickness TH4 of the light-emitting layer EML at a portion spaced apart from the lower auxiliary electrode BSE by the third length LG3. That is, the step ST may be formed in the light-emitting layer EML at a portion spaced apart from the lower auxiliary electrode BSE by the third length LG3.

Referring to FIG. 4B, a portion of the light-emitting layer EML spaced apart from the lower auxiliary electrode BSE by a fourth length LG4 may not overlap the end of the insulating portion INS. The thickness of the light-emitting layer EML may decrease at the end of the insulating portion INS.

A fifth thickness TH5 of the light-emitting layer EML at a portion spaced apart from the lower auxiliary electrode BSE by the second length LG2 may be smaller than a sixth thickness TH6 of the light-emitting layer EML at a portion spaced apart from the lower auxiliary electrode BSE by the fourth length LG4. The fourth length LG4 may be greater than the second length LG2.

A fifth length LG5 of the conductive portion CDT measured in the second direction DR2 may be smaller than the second length LG2. That is, an end of the conductive portion CDT may be positioned between the end of the insulating portion INS and the lower auxiliary electrode BSE.

Hereinafter, the structure of the auxiliary electrodes SE, SE-1 will be described in more detail with reference to FIGS. 4C and 4D.

The upper auxiliary electrode TSE may be longer in the horizontal direction than the lower auxiliary electrode BSE. Specifically, a sixth length LG6 may represent a length of the upper auxiliary electrode TSE measured in the second direction DR2, and a seventh length LG7 may represent a length of the lower auxiliary electrode BSE measured in the second direction DR2. The sixth length LG6 may be greater than the seventh length LG7.

The upper auxiliary electrode TSE may be thinner than the lower auxiliary electrode BSE. Specifically, a seventh thickness TH7 may represent a thickness of the upper auxiliary electrode TSE measured in the third direction DR3, and an eighth thickness TH8 may represent a thickness of the lower auxiliary electrode BSE measured in the third direction DR3. The seventh thickness TH7 of the upper auxiliary electrode TSE may be smaller than the eighth thickness TH8 of the lower auxiliary electrode BSE.

Referring to FIG. 4D, in one embodiment of the present disclosure, the auxiliary electrode SE-1 may further include an organic material OM disposed above the upper auxiliary electrode TSE. The organic material OM may function as a spacer. The spacer may be configured to prevent damage to the display panel DP caused by an FMM (fine metal mask) during the deposition process.

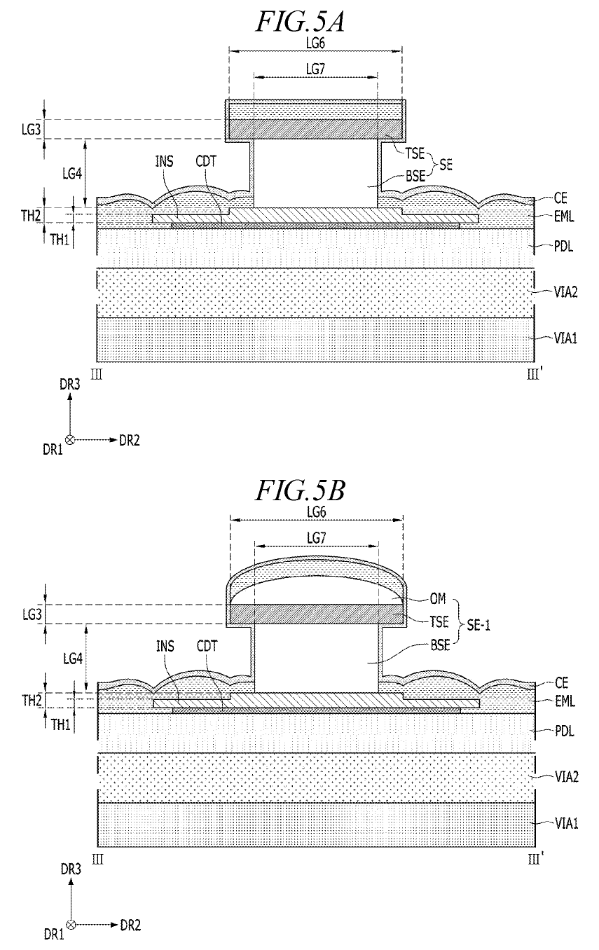

FIGS. 5A and 5B illustratively show cross-sectional views of the display panel DP taken along line III–III′ of FIG. 3B.

Referring to FIGS. 3B, 5A, and 5B, the second opening OP2 may not be defined in the pixel defining layer PDL corresponding to line III–III′. In addition, the second connection electrode CN2 overlapping the second opening OP2 may not be positioned on the first via layer VIA1 corresponding to line III–III′.

Unlike what is shown in FIGS. 4C and 4D, in FIGS. 5A and 5B, the insulating portion INS, the conductive portion CDT, the lower auxiliary electrode BSE, and the upper auxiliary electrode TSE may each be disposed on the pixel defining layer PDL.

Referring to FIG. 5B, unlike the auxiliary electrode SE shown in FIG. 5A, the auxiliary electrode SE-1 may further include an organic material OM disposed above the upper auxiliary electrode TSE.

Other descriptions related to the auxiliary electrodes SE, SE-1 are substantially the same as those described with reference to FIGS. 4A-4D and thus will not be repeated here.

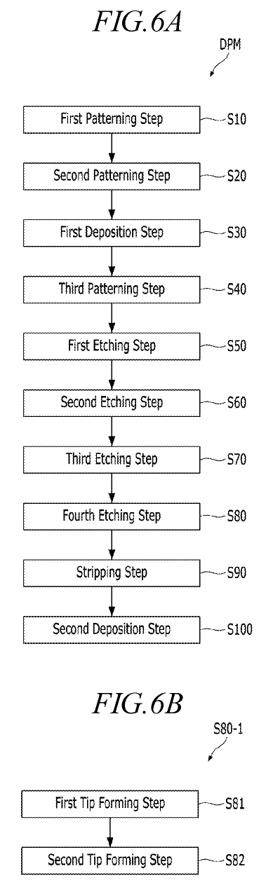

FIGS. 6A and 6B illustratively show a method of manufacturing a display panel (DPM) according to one embodiment of the present disclosure. FIGS. 7A-7I are views for illustrating respective steps of the method of manufacturing a display panel (DPM) of FIG. 6.

Referring to FIG. 6A, the method DPM may include a first patterning step S10, a second patterning step S20, a first deposition step S30, a third patterning step S40, a first etching step S50, a second etching step S60, a third etching step S70, a fourth etching step S80, a stripping step S90, and a second deposition step S100.

In FIG. 7A, a first region RG1 may correspond to line III–III′ of FIG. 3B, and a second region RG2 may correspond to line II–II′ of FIG. 3B.

Referring to FIGS. 6A and 7A, in the first patterning step S10, a conductive portion CDT in which a third opening OP3 is defined may be patterned. The conductive portion CDT may be disposed on a pixel defining layer PDL and a second connection electrode CN2, and at least a portion of the second connection electrode CN2 may overlap the third opening OP3 in a third direction DR3.

Referring to FIGS. 6A and 7B, in the second patterning step S20, an insulating portion INS in which a fourth opening OP4 is defined may be patterned. The insulating portion INS may cover at least a portion of each of the second connection electrode CN2 and the conductive portion CDT. At least a portion of the second connection electrode CN2 may overlap the fourth opening OP4 in the third direction DR3.

Referring to FIGS. 6A and 7C, in the first deposition step S30, a lower auxiliary electrode BSE and an upper auxiliary electrode TSE may be deposited on the second connection electrode CN2 and the insulating portion INS. The lower auxiliary electrode BSE may contact the second connection electrode CN2 and may cover at least a portion of the conductive portion CDT. The upper auxiliary electrode TSE may contact the lower auxiliary electrode BSE.

Referring to FIG. 7D, a first region AR1 of a halftone mask HMS may completely transmit light, a second region AR2 of the halftone mask HMS may partially transmit light, and a third region AR3 of the halftone mask HMS may completely block light.

Referring to FIGS. 6A and 7D, in the third patterning step S40, etch-resistant portions RSPa, RSPb may be patterned on the upper auxiliary electrode TSE using the halftone mask HMS. The etch-resistant portions RSPa, RSPb may include at least one of an organic material and photoresist. The organic material may be the same as that shown in FIGS. 4C and 5B.

A seventh length LG7 may be defined as a length of a part of the etch-resistant portion RSPb measured in the second direction DR2, and a sixth length LG6 may be defined as a length of a remaining part of the etch-resistant portion RSPa measured in the second direction DR2. The sixth length LG6 may be greater than the seventh length LG7.

Referring to FIGS. 6A and 7E, in the first etching step S50, at least a portion of each of the lower auxiliary electrode BSE and the upper auxiliary electrode TSE may be etched. The etched lower auxiliary electrode BSE and the etched upper auxiliary electrode TSE may each have the sixth length LG6 when measured in the second direction DR2.

Referring to FIGS. 6A and 7F, in the second etching step S60, a portion of the insulating portion INS that does not overlap the part of the etch-resistant portion RSPb in the third direction DR3 may be etched. In the second etching step S60, the part of the etch-resistant portion RSPb may be removed by PR ashing, and only the remaining part of the etch-resistant portion RSPa remains on the upper auxiliary electrode TSE.

Referring to FIGS. 6A and 7G, in the third etching step S70, at least portions of each of the lower auxiliary electrode BSE, the upper auxiliary electrode TSE, and the insulating portion INS may be etched. The etched lower auxiliary electrode BSE and etched upper auxiliary electrode TSE may each have the seventh length LG7 when measured in the second direction DR2.

A first thickness TH1 of a portion of the etched insulating portion INS overlapping the upper auxiliary electrode TSE may be greater than a second thickness TH2 of another portion of the insulating portion INS not overlapping the upper auxiliary electrode TSE. In the third etching step S70, a step ST may be formed in the insulating portion INS.

Referring to FIGS. 6A, 7H, and 7I, in the fourth etching step S80, at least a portion of each of the lower auxiliary electrode BSE and the conductive portion CDT may be etched.

Referring to FIG. 6A, in one embodiment of the present disclosure, the fourth etching step S80 may be a single step.

A first tip TP1 refers to a portion in which the upper auxiliary electrode TSE protrudes further than the lower auxiliary electrode BSE, and a second tip TP2 refers to a portion in which the insulating portion INS protrudes further than the conductive portion CDT.

Referring to FIGS. 7H and 7I, in the fourth etching step S80, at least a portion of the lower auxiliary electrode BSE and at least a portion of the conductive portion CDT may be etched. An eighth length LG8, measured in the second direction DR2 from the etched lower auxiliary electrode BSE, may be smaller than the seventh length LG7. That is, the first tip TP1 may be formed in the upper auxiliary electrode TSE.

An end of the etched conductive portion CDT may be spaced apart from the upper auxiliary electrode TSE by a ninth length LG9 in the second direction DR2, and an end of the etched insulating portion INS may be spaced apart from the upper auxiliary electrode TSE by a tenth length LG10, which is greater than the ninth length LG9, in the second direction DR2. That is, the second tip TP2 may be formed in the insulating portion INS.

Referring to FIG. 6B, in another embodiment of the present disclosure, the fourth etching step S80 may include a first tip forming step S81 and a second tip forming step S82.

Referring to FIGS. 6B and 7H, in the first tip forming step S81, at least a portion of the lower auxiliary electrode BSE may be etched by wet etching. The eighth length LG8, measured in the second direction DR2 from the etched lower auxiliary electrode BSE, may be smaller than the seventh length LG7. That is, in the first tip forming step S81, the first tip TP1 may be formed in the upper auxiliary electrode TSE.

In the first tip forming step S81 according to one embodiment of the present disclosure, a basic substance may be used. For example, the basic substance may include KOH, TMAH (tetramethyl ammonium hydroxide), NH₄OH, or NaOH. However, the basic substance of the present disclosure is not limited thereto but may be sufficient as long as it can etch the lower auxiliary electrode BSE without etching the insulating portion INS or the conductive portion CDT.

Referring to FIGS. 6B and 7I, in the second tip forming step S82, at least a portion of the conductive portion CDT may be etched. An end of the etched conductive portion CDT may be spaced apart from the upper auxiliary electrode TSE by the ninth length LG9 in the second direction DR2. An end of the insulating portion INS may be spaced apart from the upper auxiliary electrode TSE by the tenth length LG10, which is greater than the ninth length LG9, in the second direction DR2. The insulating portion INS may protrude further than the conductive portion CDT. That is, in the second tip forming step S82, the second tip TP2 may be formed in the insulating portion INS.

In the second tip forming step S82 according to one embodiment of the present disclosure, an acidic substance may be used. For example, the acidic substance may include HF, HCl, HNO₃, H₃PO₄, C₂H₄O₃, HNO₃ + CH₃COOH, or HCl + HNO₃. However, the acidic substance of the present disclosure is not limited thereto but may be sufficient as long as it can etch the conductive portion CDT.

Referring to FIGS. 6A and 7J, in the stripping step S90, the remaining part of the etch-resistant portion RSPa may be removed.

Referring to FIGS. 4A, 4C, and 5A, in one embodiment of the present disclosure, the etch-resistant portions RSPa, RSPb may be photoresist, and in the stripping step S90, one part of the etch-resistant portion RSPb may be removed through a PR strip process.

Referring to FIGS. 4D and 5B, in another embodiment of the present disclosure, the etch-resistant portions RSPa, RSPb may include the organic material OM, and the stripping step S90 may be omitted.

Referring to FIGS. 6A and 7K, in the second deposition step S100, an light-emitting layer EML covering at least a portion of the cathode electrode CE and the conductive portion CDT may be deposited. The cathode electrode CE may be deposited on at least one of the upper auxiliary electrode TSE and the lower auxiliary electrode BSE. The light-emitting layer EML may be disposed between the cathode electrode CE and the pixel defining layer PDL. In the present disclosure, the auxiliary electrode SE may be provided in plural. Since each of the plurality of auxiliary electrodes SE is formed by etching, the distance between the first tip TP1 and the second tip TP2 in the plurality of auxiliary electrodes SE may be uniform. Accordingly, the design tolerance of each of the lower auxiliary electrode BSE and the upper auxiliary electrode TSE for securing the distance between the first tip TP1 and the second tip TP2 may be minimized. As a result, each of the lower auxiliary electrode BSE and the upper auxiliary electrode TSE may be disposed in as wide an area as possible to effectively suppress voltage drop.

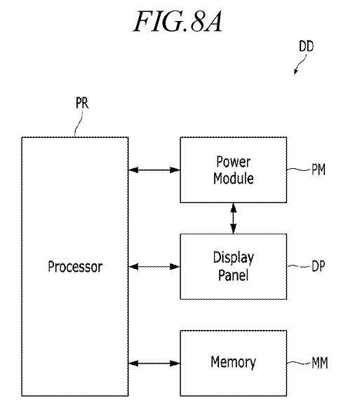

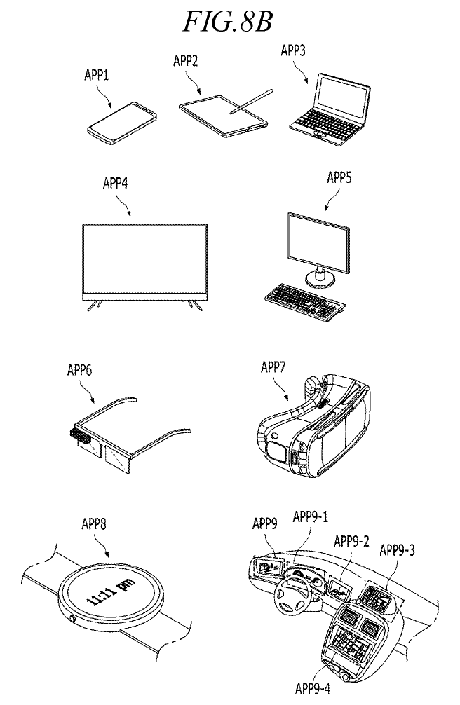

FIG. 8A is a block diagram illustrating an electronic device ED according to one embodiment of the present disclosure. FIG. 8B illustrates various forms of the electronic device ED according to embodiments of the present disclosure. Referring to FIGS. 8A, the electronic device ED according to one embodiment may include a display panel DP, a processor PR, a memory MM, and a power module PM.

The processor PR may include at least one of a central processing unit (CPU), an application processor (AP), a graphic processing unit (GPU), a communication processor (CP), an image signal processor (ISP), and a controller.

The memory MM may have stored therein data information necessary for operating at least one of the processor PR and the display panel DP. When the processor PR executes an application stored in the memory MM, image data signals and/or input control signals may be transferred to the display panel DP, which then may process the received signals to output image information through a display screen.

The power module PM may include a power supply module, such as a power adapter or a battery device, and a power conversion module configured to convert the power supplied by the power supply module to generate the power required for operating the electronic device ED.

At least one of the components of the above-described electronic device DD may be included in a display device according to the above-described embodiments. Also, among individual modules functionally included in one module, some may be included in the display device, while others may be provided separately from the display device. For example, the display device may include the display panel DP, and the processor PR, the memory MM, and the power module PM may be provided in another device within the electronic device DD, rather than in the display device.

Referring to FIG. 8B, various electronic devices DD to which the display panel DP according to embodiments of the present disclosure is applied may include not only image display electronic devices, such as a smartphone APP1, a tablet PC APP2, a laptop computer APP3, a TV APP4, and a desktop monitor APP5, but also wearable electronic devices including the display panel DP, such as smart glasses APP6, a head-mounted display APP7, and a smart watch APP8, as well as automotive electronic devices APP9 to APP9-4 including the display panel, such as an instrument panel, a center fascia, a dashboard-mounted CID (Center Information Display), or a room mirror display.

Although the present display device has been described with reference to the embodiments shown in the drawings, these are merely exemplary, and those skilled in the art will understand that various modifications and equivalent other embodiments are possible therefrom. Therefore, the disclosed subject matter should not be limited to any single embodiment described herein.

What is claimed is:

1. A display panel, comprising:
a semiconductor portion including a semiconductor material;
a first via layer disposed on the semiconductor portion;
a first connection electrode disposed on the first via layer, wherein the first connection electrode passes through the first via layer and is electrically connected to the semiconductor portion;
a second connection electrode disposed on the first via layer, the second connection electrode being spaced apart from the first connection electrode;
a pixel defining layer disposed on the first via layer and having a first opening and a second opening defined therein;
a light-emitting diode including an anode electrode, a light-emitting layer, and a cathode electrode, the anode electrode overlapping the first opening of the pixel defining layer, and the anode electrode being electrically connected to the first connection electrode;
an auxiliary electrode including a lower auxiliary electrode and an upper auxiliary electrode, wherein the upper auxiliary electrode is disposed on the lower auxiliary electrode, and wherein the lower auxiliary electrode overlaps the second opening of the pixel defining layer, the lower auxiliary electrode being in contact with the second connection electrode, and at least one of the lower auxiliary electrode or the upper auxiliary electrode being in contact with the cathode electrode; and
an insulating portion, wherein at least a part of the insulating portion is disposed on the pixel defining layer and is in contact with the lower auxiliary electrode,
wherein a length of a portion of the insulating portion not overlapping the upper auxiliary electrode, measured in a predetermined direction, is greater than a distance between the insulating portion and the upper auxiliary electrode.

2. The display panel of claim 1, wherein a thickness of a portion of the insulating portion overlapping the upper auxiliary electrode is greater than a thickness of the portion of the insulating portion not overlapping the upper auxiliary electrode.

3. The display panel of claim 2, wherein a first portion of the insulating portion is disposed between the pixel defining layer and the lower auxiliary electrode, and a second portion of the insulating portion is in contact with the second connection electrode,
wherein at least a portion of the light-emitting layer covers at least a third portion of the insulating portion, and
wherein the cathode electrode covers the light-emitting layer.

4. The display panel of claim 3, wherein a first length is a length, measured in the predetermined direction, of a portion of the upper auxiliary electrode not overlapping the lower auxiliary electrode, and a second length is a length, measured in the predetermined direction, of a portion of the insulating portion not overlapping the lower auxiliary electrode,
wherein a thickness of a portion of the light-emitting layer spaced apart from the lower auxiliary electrode by the first length is smaller than a thickness of a portion of the light-emitting layer spaced apart from the lower auxiliary electrode by a third length, the third length being greater than the first length, and the third length being smaller than the second length, and
wherein a thickness of a portion of the light-emitting layer spaced apart from the lower auxiliary electrode by the second length is smaller than a thickness of a portion of the light-emitting layer spaced apart from the lower auxiliary electrode by a fourth length, the fourth length being greater than the second length.

5. The display panel of claim 2, wherein the first connection electrode and the second connection electrode are configured to receive different voltages.

6. The display panel of claim 2, further comprising:
a base substrate disposed below the semiconductor portion;
a gate insulating layer disposed on the semiconductor portion;
a gate portion disposed between the gate insulating layer and the first connection electrode, at least a portion of the gate portion overlapping the semiconductor portion; and
a second via layer disposed between the first via layer and the pixel defining layer, and the second via layer covering at least a portion of each of the first connection electrode and the second connection electrode.

7. The display panel of claim 4, further comprising a conductive portion disposed between the pixel defining layer and the insulating portion,
wherein, a fifth length of the conductive portion, measured in the predetermined direction, is less than the second length.

8. The display panel of claim 3, wherein a sixth length of the upper auxiliary electrode, measured in the predetermined direction, is greater than a seventh length of the lower auxiliary electrode, measured in the predetermined direction, and
wherein a thickness of the upper auxiliary electrode is less than a thickness of the lower auxiliary electrode.

9. The display panel of claim 7, wherein the insulating portion comprises an insulating material,
wherein the conductive portion comprises a transparent conductive material,
wherein the lower auxiliary electrode comprises a first metal material,
wherein the upper auxiliary electrode comprises a second metal material different from the first metal material, and
wherein the first connection electrode and the second connection electrode comprise a same conductive material.

10. A display panel, comprising:
a transistor including an input electrode, an output electrode, and a control electrode;
a first via layer disposed on the transistor;
a first connection electrode disposed on the first via layer, wherein the first connection electrode is electrically connected to one of the input electrode and the output electrode;
a second connection electrode disposed on the first via layer, wherein the second connection electrode is spaced apart from the first connection electrode;
a pixel defining layer disposed on the first via layer;
a light-emitting diode including an anode electrode, a light-emitting layer, and a cathode electrode, wherein the anode electrode is electrically connected to the first connection electrode;
an auxiliary electrode including a lower auxiliary electrode and an upper auxiliary electrode, wherein the upper auxiliary electrode is disposed on the lower auxiliary electrode, and wherein the lower auxiliary electrode being in contact with the second connection electrode, and at least one of the lower auxiliary electrode or the upper auxiliary electrode is in contact with the cathode electrode; and
an insulating portion, wherein at least a part of the insulating portion is disposed on the pixel defining layer and is in contact with the lower auxiliary electrode,
wherein a length of a portion of the insulating portion not overlapping the upper auxiliary electrode, measured in a predetermined direction, is greater than a distance between the insulating portion and the upper auxiliary electrode.

11. The display panel of claim 10, wherein a thickness of a portion of the insulating portion overlapping the upper auxiliary electrode is greater than a thickness of the portion of the insulating portion not overlapping the upper auxiliary electrode.

12. The display panel of claim 11, wherein a first portion of the insulating portion is disposed between the pixel defining layer and the lower auxiliary electrode, and a second portion of the insulating portion is in contact with the second connection electrode,
wherein at least a portion of the light-emitting layer covers at least a third portion of the insulating portion, and
wherein the cathode electrode covers the light-emitting layer.

13. The display panel according to claim 12, wherein a first length is a length, measured in the predetermined direction, of a portion of the upper auxiliary electrode not overlapping the lower auxiliary electrode, and a second length is a length, measured in the predetermined direction, of a portion of the insulating portion not overlapping the lower auxiliary electrode,
wherein a thickness of a portion of the light-emitting layer spaced apart from the lower auxiliary electrode by the first length is smaller than a thickness of a portion of the light-emitting layer spaced apart from the lower auxiliary electrode by a third length, the third length being greater than the first length, and the third length being smaller than the second length, and
wherein a thickness of a portion of the light-emitting layer spaced apart from the lower auxiliary electrode by the second length is smaller than a thickness of a portion of the light-emitting layer spaced apart from the lower auxiliary electrode by a fourth length, the fourth length being greater than the second length.

14. The display panel according to claim 11, wherein the first connection electrode and the second connection electrode are configured to receive different voltages.

15. The display panel according to claim 11, further comprising:
a base substrate disposed below the transistor; and
a second via layer disposed between the first via layer and the pixel defining layer, and the second via layer covering at least a portion of each of the first connection electrode and the second connection electrode.

16. The display panel of claim 11, further comprising a conductive portion disposed between the pixel defining layer and the insulating portion,
wherein a fifth length of the conductive portion, measured in the predetermined direction, is less than the second length.

17. The display panel of claim 12, wherein a sixth length of the upper auxiliary electrode, measured in the predetermined direction, is greater than a seventh length of the lower auxiliary electrode, measured in the predetermined direction, and
wherein a thickness of the upper auxiliary electrode is less than a thickness of the lower auxiliary electrode.

18. The display panel of claim 16, wherein the insulating portion comprises an insulating material,
wherein the conductive portion comprises a transparent conductive material,
wherein the lower auxiliary electrode comprises a first metal material,
wherein the upper auxiliary electrode comprises a second metal material different from the first metal material, and
wherein the first connection electrode and the second connection electrode comprise a same conductive material.

19. An electronic device, comprising:
a display panel configured to emit light;
a processor configured to control the display panel;
a memory in which data necessary for operating the display panel or the processor is stored; and
a power module configured to generate or supply power,
wherein the display panel comprises:
a semiconductor portion including a semiconductor material;
a first via layer disposed on the semiconductor portion;
a first connection electrode disposed on the first via layer, and the first connection electrode passing through the first via layer thereby electrically being connected to the semiconductor portion;
a second connection electrode disposed on the first via layer, and the second connection electrode being spaced apart from the first connection electrode;
a pixel defining layer disposed on the first via layer and having a first opening and a second opening defined therein;
a light-emitting diode including an anode electrode, a light-emitting layer, and a cathode electrode, the anode electrode overlapping the first opening of the pixel defining layer and the anode electrode being electrically connected to the first connection electrode;
an auxiliary electrode including a lower auxiliary electrode and an upper auxiliary electrode, wherein the upper auxiliary electrode is disposed on the lower auxiliary electrode, and wherein the lower auxiliary electrode overlaps the second opening of the pixel defining layer, and the lower auxiliary electrode being in contact with the second connection electrode, and at least one of the lower auxiliary electrode or the upper auxiliary electrode being in contact with the cathode electrode; and
an insulating portion, wherein at least a part of the insulating portion is disposed on the pixel defining layer and is in contact with the lower auxiliary electrode,
wherein a length of a portion of the insulating portion not overlapping the upper auxiliary electrode, measured in a predetermined direction, is greater than a distance between the insulating portion and the upper auxiliary electrode.

20. The electronic device of claim 19, wherein a thickness of a portion of the insulating portion overlapping the upper auxiliary electrode is greater than a thickness of the portion of the insulating portion not overlapping the upper auxiliary electrode.
